(19) United States
(12) Patent Application Publication
(10) Pub. No.: US 2023/0298984 A1
(43) Pub. Date: Sep. 21, 2023

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventors: Atsushi MAEDA, Tokyo (JP); Tatsuya KAWASE, Tokyo (JP)

(73) Assignee: Mitsubishi Electric Corporation, Tokyo (JP)

(21) Appl. No.: 18/004,429

(22) PCT Filed: Dec. 17, 2020
(86) PCT No.: PCT/JP2020/047262

§ 371 Date: Jan. 5, 2023

(51) Int. Cl. H01L 23/498; H01L 21/60

(52) U.S. Cl. CPC H01L 23/49811; H01L 21/60; H01L 2021/60007

(57) ABSTRACT

A semiconductor device according to the disclosure includes a substrate, a semiconductor chip provided on the substrate, a nut, a lead frame provided on the semiconductor chip and the nut and screwed to the nut, a nut box accommodating the nut and having an opening which exposes the nut downward formed in a bottom portion and solder provided at least between the semiconductor chip and the substrate or the lead frame.

### FIELD

The present disclosure relates to a semiconductor device and a method for manufacturing the semiconductor device.

### BACKGROUND

PTL 1 discloses a method for manufacturing a power semiconductor device. In the manufacturing method, an insulating layer and a metal circuit layer are made to adhere on a metal substrate, a heat dissipation plate is arranged on an upper surface of the metal circuit layer with a solder sheet interposed therebetween, and a silicon semiconductor chip is arranged on an upper surface of the heat dissipation plate with a solder sheet interposed therebetween. A one-side terminal section of a lead frame is arranged on an upper surface of the silicon semiconductor chip with a solder sheet interposed therebetween. The whole of the components is heated to melt all the solder sheets. As a result, the metal circuit layer and the heat dissipation plate, the heat dissipation plate and the silicon semiconductor chip, and the silicon semiconductor chip and the one-side terminal section of the lead frame are respectively collectively bonded to each other.

### CITATION LIST

### Patent Literature

[PTL 1] JP 2007-157863 A

### SUMMARY

### Technical Problem

In a solder bonding process as described in PTL 1, solder may be heated from the substrate side and melted. In this case, it may take time to melt the solder.

The present disclosure is directed to obtaining a semiconductor device capable of melting solder in a short time period and a method for manufacturing the semiconductor device.

### Solution to Problem

A semiconductor device according to the first disclosure includes a substrate, a semiconductor chip provided on the substrate, a nut, a lead frame provided on the semiconductor chip and the nut and screwed to the nut, a nut box accommodating the nut and having an opening which exposes the nut downward formed in a bottom portion and solder provided at least between the semiconductor chip and the substrate or the lead frame.

A method for manufacturing a semiconductor device according to the second disclosure includes a substrate, a semiconductor chip provided on the substrate, a nut, a lead frame provided on the semiconductor chip and the nut, a nut box accommodating the nut and having an opening which exposes the nut downward formed in a bottom portion, and solder provided at least between the semiconductor chip and the substrate or the lead frame, the method comprising, loading the semiconductor device on a lower jig having a projection on an upper surface and bringing the projection into contact with the nut through the opening, and heating the lower jig with the projection brought into contact with the nut and bonding the semiconductor chip and the substrate or the lead frame to each other with the solder.

A method for manufacturing a semiconductor device according to the third disclosure includes a substrate, a semiconductor chip provided on the substrate, a lead frame provided on the semiconductor chip, solder provided at least between the semiconductor chip and the substrate or the lead frame, and a case surrounding the semiconductor chip, the method comprising, loading the semiconductor device on a lower jig having a projection formed of a metal on an upper surface and bringing the projection into contact with the lead frame, and heating the lower jig with the projection brought into contact with the lead frame and bonding the semiconductor chip and the substrate or the lead frame to each other with the solder.

### Advantageous Effects of Invention

In a semiconductor device and a method for manufacturing the semiconductor device according to the present disclosure, heat can be transferred to solder via a lead frame. Therefore, the solder can be melted in a short time period.

### BRIEF DESCRIPTION OF DRAWINGS

FIG. 1 is a cross-sectional view of a semiconductor device according to an embodiment 1.

FIG. 2 is a flowchart illustrating a method for manufacturing the semiconductor device according to the embodiment 1.

FIG. 3 is a cross-sectional view of a semiconductor device according to a comparative example.

FIG. 4 is a cross-sectional view of a semiconductor device according to an embodiment 2.

FIG. 5 is a cross-sectional view of a semiconductor device according to an embodiment 3.

FIG. 6 is a cross-sectional view of a semiconductor device according to an embodiment 4.

FIG. 7 is a cross-sectional view of a semiconductor device according to an embodiment 5.

### DESCRIPTION OF EMBODIMENTS

A semiconductor device and a method for manufacturing the semiconductor device according to each embodiment of the present disclosure are described with reference to drawings. Identical or corresponding constitutional elements are given the same reference numerals, and the repeated description of such constitutional elements may be omitted.

### Embodiment 1

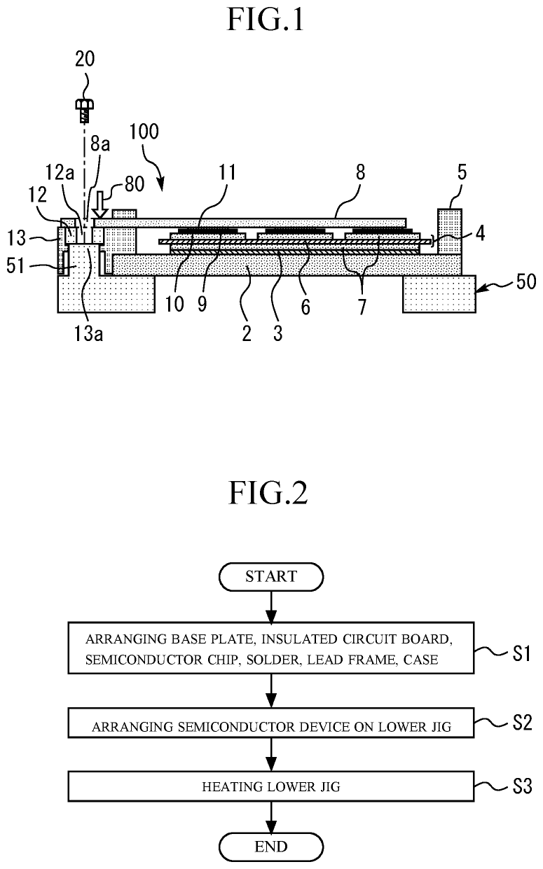

FIG. 1 is a cross-sectional view of a semiconductor device 100 according to an embodiment 1. The semiconductor device 100 has a DLB (direct lead bonding) structure in which a lead frame 8 is directly solder-bonded to a semiconductor chip 10. The semiconductor device 100 includes a base plate 2 and an insulated circuit board 4 bonded with solder 3 to a central portion on an upper surface of the base plate 2. A case 5 is fixed to an outer peripheral portion on the upper surface of the base plate 2 with an adhesive material or the like. The base plate 2 is formed of Cu, Al, or AlSiC, for example.

The insulated circuit board 4 includes an insulating substrate 6 and circuit patterns 7 respectively provided on an upper surface and a rear surface of the insulating substrate 6. The circuit pattern 7 provided on the rear surface of the insulating substrate 6 is fixed to the base plate 2 with the solder 3 interposed therebetween. The circuit pattern 7 provided on the upper surface of the insulating substrate 6 constitutes an electrical circuit. Accordingly, the circuit pattern 7 provided on the upper surface of the insulating substrate 6 has a lower coverage with the insulating substrate 6 than the circuit pattern 7 provided on the rear surface thereof. The insulating substrate 6 is formed of Al₂O₃, AlN, or Si₃N₄, for example. The circuit pattern 7 is formed of Al or Cu, for example.

A plurality of semiconductor chips 10 are provided on the insulated circuit board 4. Respective rear surfaces of the plurality of semiconductor chips 10 are fixed to the circuit pattern 7 provided on the upper surface of the insulating substrate 6 with solder 9 interposed therebetween. The solder 9 is formed of a paste solder or a plate solder, for example. The semiconductor chip 10 is made with Si, for example. The semiconductor chip 10 may be made with a wide bandgap semiconductor. An example of the wide bandgap semiconductor is silicon carbide, a gallium nitride-based material, or diamond.

The lead frame 8 is provided on the plurality of semiconductor chips 10 and a nut 12, described below. The lead frame 8 is bonded to respective upper surfaces of the semiconductor chips 10 with solder 11 interposed therebetween. The solder 11 is formed of a paste solder or a plate solder, for example. The lead frame 8 is formed of Cu or Al, for example. The lead frame 8 is fixed to the case 5. The case 5 surrounds the insulated circuit board 4 and the plurality of semiconductor chips 10. The case 5 is formed of PPS (poly phenylene sulfide), for example.

A screw hole 12a is formed in the nut 12. The screw hole 12a overlaps a through hole 8a formed in the lead frame 8 in a planar view. The nut 12 and the lead frame 8 are screwed to each other with a screw 20 via the through hole 8a and the screw hole 12a. The nut 12 is formed of aluminum, stainless, or titanium, for example.

A nut box 13 accommodates the nut 12. The nut box 13 opens on the side provided with the lead frame 8. The nut 12 is in contact with the lead frame 8 with the nut 12 accommodated in the nut box 13. The nut box 13 has an opening 13a which exposes the nut 12 downward formed in its bottom portion.

The nut box 13 is provided outside a region of the case 5 which accommodates the semiconductor chips 10. The nut box 13 is fixed to the case 5. The nut box 13 may be a part of the case 5. The nut box 13 is formed of PPS, for example.

A lower jig 50 is used in a process for manufacturing the semiconductor device 100. The lower jig 50 has a projection 51 on its upper surface. The lower jig 50 is installed to contact the base plate 2. The projection 51 is installed to contact the nut 12 through the opening 13a. The lower jig 50 and the projection 51 are each formed of a metal such as stainless steel.

FIG. 2 is a flowchart illustrating a method for manufacturing the semiconductor device 100 according to the embodiment 1. First, in step S1, a base plate 2, an insulated circuit board 4, a semiconductor chip 10, solders 3, 9, and 11, a lead frame 8, a case 5, a nut 12, and a nut box 13 are each arranged at loading positions, as illustrated in FIG. 1. That is, the insulated circuit board 4 is arranged on the base plate 2 with the solder 3 interposed therebetween, and the semiconductor chip 10 is arranged on the insulated circuit board 4 with the solder 9 interposed therebetween. The nut 12 is accommodated in the nut box 13. The lead frame 8 is arranged on the semiconductor chip 10 with the solder 11 interposed therebetween. The case 5 is arranged on the base plate 2. An end portion of the lead frame 8 is arranged on the nut 12.

Then, in step S2, the semiconductor device 100 is arranged on a lower jig 50. At this time, a projection 51 contacts the nut 12 through an opening 13a of the nut box 13. Then, in step S3, the lower jig 50 is heated with the projection 51 brought into contact with the nut 12. Accordingly, the solders 3, 9, and 11 are heated via the base plate 2. Further, the solders 3, 9, and 11 are heated via the nut 12 and the lead frame 8. As a result, the solders 3, 9, and 11 are melted. Therefore, the base plate 2 and the insulated circuit board 4, the semiconductor chip 10 and the insulated circuit board 4, and the semiconductor chip 10 and the lead frame 8 are respectively bonded to each other with the solders 3, 9, and 11.

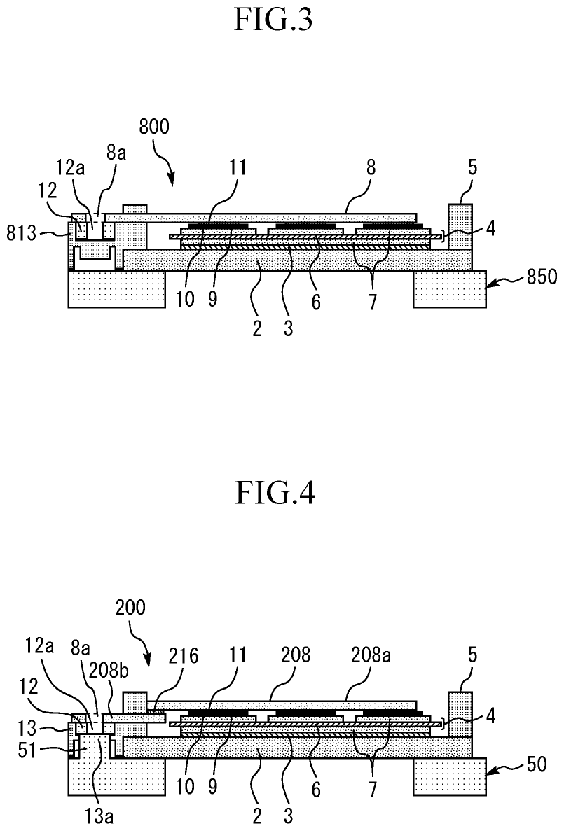

FIG. 3 is a cross-sectional view of a semiconductor device 800 according to a comparative example. The semiconductor device 800 according to the comparative example differs from the semiconductor device 100 in that an opening is not formed on a bottom portion of a nut box 813. In the semiconductor device 800 according to the comparative example, when a lower jig 850 is heated, solders 3, 9, and 11 are heated via a base plate 2 and are melted. At this time, it may take time to melt the solders 3, 9, and 11.

On the other hand, in the present embodiment, the projection 51 of the lower jig 50 and the nut 12 are brought into contact with each other, whereby heat can be transferred to the solders 3, 9, and 11 via the lead frame 8. Therefore, the solders 3, 9, and 11 can be melted in a short time period. This makes it possible to improve takt for a solder bonding process.

When heat is efficiently transferred to the solders 3, 9, and 11 from the base plate 2 and the lead frame 8, the solders 3, 9, 11 can be reliably melted. Therefore, the reliability of the semiconductor device 100 can be improved.

As a modification to the present embodiment, the projection 51 may have a thermal conductivity higher than that of a portion, other than the projection 51, of the lower jig 50. The projection 51 is formed of Cu, for example. This makes it possible to efficiently transfer heat to the lead frame 8 and makes it easy to transfer heat to the solders 3, 9, and 11.

In step S3, the lower jig 50 may be heated with the lead frame 8 pressed toward the projection 51, as indicated by an arrow 80 in FIG. 1. Pressurization is performed using a plunger, for example. This makes it possible to reduce a contact thermal resistance between the lower jig 50 and the lead frame 8. This makes it easy to transfer heat to the solders 3, 9, and 11.

A configuration of the semiconductor device 100 is not limited to that illustrated in FIG. 1. Although the three semiconductor chips 10 are illustrated in FIG. 1, the number of semiconductor chips 10 to be provided in the semiconductor device 100 may be one or more. The case 5 may be fixed to the insulated circuit board 4. Solder may be provided at least between the semiconductor chip 10 and the insulated circuit board 4 or the lead frame 8.

These modifications can be applied, as appropriate, to semiconductor devices and methods for manufacturing the semiconductor devices according to the following embodiments. Note that the semiconductor devices and the methods for manufacturing the semiconductor devices according to the following embodiments are similar to those of the first embodiment in many respects, and thus differences between the semiconductor devices and the methods for manufacturing the semiconductor devices according to the following embodiments and those of the first embodiment will be mainly described below.

### Embodiment 2

FIG. 4 is a cross-sectional view of a semiconductor device 200 according to an embodiment 2. The semiconductor device 200 differs from the semiconductor device 100 in a configuration of a lead frame 208. Other components are similar to those in the embodiment 1. The lead frame 208 includes a main body section 208a and an external connection terminal section 208b. The main body section 208b is provided directly above a semiconductor chip 10. The external connection terminal section 208b is bonded to the main body section 208a with solder 216, and is provided directly above a nut 12. The main body section 208a and the external connection terminal section 208b are each formed of Cu or Al, for example. The external connection terminal section 208b is fixed by a case 5.

In the present embodiment, heat can be transferred to the solder 216 from a lower jig 50 via the nut 12 and the external connection terminal section 208b. Therefore, even when the lead frame 208 includes a solder bonding section, the solder 216 can also be melted in a short time period.

### Embodiment 3

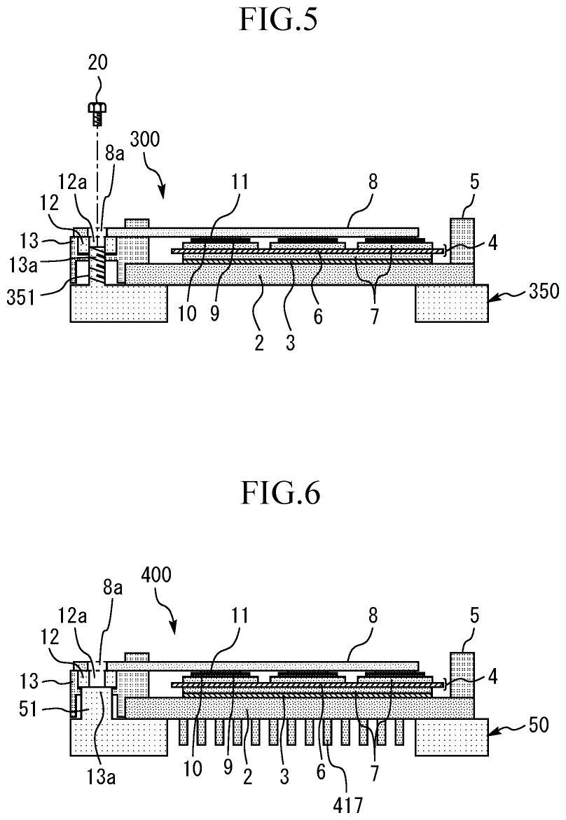

FIG. 5 is a cross-sectional view of a semiconductor device 300 according to an embodiment 3. In a process for manufacturing the semiconductor device 300, a projection 351 of a lower jig 350 is inserted into a screw hole 12a of a nut 12. The projection 351 is threaded and is screwed to the nut 12. A lead frame 8 and the nut 12 are screwed to each other with a screw 20. The lower jig 350 is heated with the projection 351 and the nut 12 and the lead frame 8 and the nut 12 are respectively screwed to each other. This makes it possible to reduce respective contact thermal resistances between the projection 351 and the nut 12 and between the nut 12 and the lead frame 8. Therefore, heat is easily transferred to solders 3, 9, and 11. The lower jig 350 may be heated with only either the projection 351 and the nut 12 or the nut 12 and the lead frame 8 are screwed to each other.

### Embodiment 4

FIG. 6 is a cross-sectional view of a semiconductor device 400 according to an embodiment 4. The semiconductor device 400 differs from the semiconductor device 100 in that a fin 417 is provided below an insulated circuit board 4. Other components are similar to those in the embodiment 1. The fin 417 is provided on a rear surface of a base plate 2. The fin 417 is a pin fin, for example. This makes it possible to improve a cooling performance of the semiconductor device 400. The fin 417 may be a part of the base plate 2, or may be a component separate from the base plate 2.

### Embodiment 5

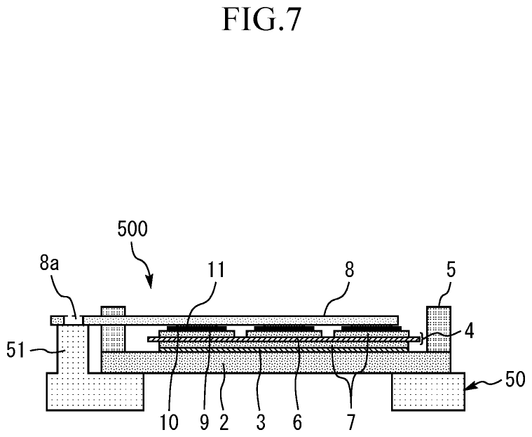

FIG. 7 is a cross-sectional view of a semiconductor device 500 according to an embodiment 5. The semiconductor device 500 differs from the semiconductor device 100 in that a nut 12 and a nut box 13 are not provided. Other components are similar to those in the embodiment 1.

Then, a method for manufacturing a semiconductor device 500 will be described. An insulated circuit board 4 is arranged on a base plate 2 with solder 3 interposed therebetween, and a semiconductor chip 10 is arranged on the insulated circuit board 4 with solder 9 interposed therebetween. A lead frame 8 is arranged on the semiconductor chip 10 with solder 11 interposed therebetween. A case 5 is arranged on the base plate 2.

Then, the semiconductor device 500 is loaded on a lower jig 50, to bring a projection 51 into contact with the lead frame 8. Then, the lower jig 50 is heated with the projection 51 brought into contact with the lead frame 8. The projection 51 of the lower jig 50 is formed of a metal. As a result, solders 3, 9, and 11 are heated via the base plate 2. Further, the solders 3, 9, and 11 are heated via the lead frame 8. As a result, the solders 3, 9, and 11 are melted. Therefore, the base plate 2 and the insulated circuit board 4, the semiconductor chip 10 and the insulated circuit board 4, and the semiconductor chip 10 and the lead frame 8 are respectively bonded to each other by the solders 3, 9, and 11.

In the present embodiment, the projection 51 of the lower jig 50 and the lead frame 8 are brought into contact with each other, whereby heat can be transferred to the solders 3, 9, and 11 via the lead frame 8. Therefore, the solders 3, 9, and 11 can be melted in a short time period. This makes it possible to improve takt for a solder bonding process.

Note that the technical features described in the above embodiments may be combined as appropriate.

### REFERENCE SIGNS LIST

2 base plate, 4 insulated circuit board, 5 case, 6 insulating substrate, 7 circuit pattern, 8 lead frame, 8a through hole, 10 semiconductor chip, 12 nut, 12a screw hole, 13 nut box, 13a opening, 20 screw, 50 lower jig, 51 projection, 100, 200 semiconductor device, 208 lead frame 208a main body section, 208b external connection terminal section, 300 semiconductor device, 350 lower jig, 351 projection, 400 semiconductor device, 417 fin, 500, 800 semiconductor device, 813 nut box 850 lower jig

1. A semiconductor device comprising:
a substrate;
a semiconductor chip provided on the substrate;
a nut;
a lead frame provided on the semiconductor chip and the nut and screwed to the nut;
a nut box accommodating the nut and having an opening which exposes the nut downward formed in a bottom portion; and
solder provided at least between the semiconductor chip and the substrate or the lead frame.

2. The semiconductor device according to claim 1, wherein the lead frame and the nut contact each other.

3. The semiconductor device according to claim 1, further comprising
a case surrounding the semiconductor chip,
wherein the nut box is provided in the case.

4. The semiconductor device according to claim 1, wherein the lead frame includes a main body section provided directly above the semiconductor chip and an external connection terminal section bonded to the main body section with solder and provided directly above the nut.

5. The semiconductor device according to claim 1, further comprising a fin provided below the substrate.

6. The semiconductor device according to claim 1, wherein the semiconductor chip is made with a wide bandgap semiconductor.

7. The semiconductor device according to claim 6, wherein the wide bandgap semiconductor is silicon carbide, a gallium nitride-based material, or diamond.

8. A method for manufacturing a semiconductor device comprising a substrate, a semiconductor chip provided on the substrate, a nut, a lead frame provided on the semiconductor chip and the nut, a nut box accommodating the nut and having an opening which exposes the nut downward formed in a bottom portion, and solder provided at least between the semiconductor chip and the substrate or the lead frame,
the method comprising;
loading the semiconductor device on a lower jig having a projection on an upper surface and bringing the projection into contact with the nut through the opening; and
heating the lower jig with the projection brought into contact with the nut and bonding the semiconductor chip and the substrate or the lead frame to each other with the solder.

9. A method for manufacturing a semiconductor device comprising a substrate, a semiconductor chip provided on the substrate, a lead frame provided on the semiconductor chip, solder provided at least between the semiconductor chip and the substrate or the lead frame, and a case surrounding the semiconductor chip,
the method comprising:
loading the semiconductor device on a lower jig having a projection formed of a metal on an upper surface and bringing the projection into contact with the lead frame; and
heating the lower jig with the projection brought into contact with the lead frame and bonding the semiconductor chip and the substrate or the lead frame to each other with the solder.

10. The method for manufacturing the semiconductor device according to claim 8, wherein the projection has a thermal conductivity higher than that of a portion, other than the projection, of the lower jig.

11. The method for manufacturing the semiconductor device according to claim 8, wherein the lower jig is heated with the lead frame pressed toward the projection.

12. The method for manufacturing the semiconductor device according to claim 8, wherein the projection is threaded and is screwed to the nut.

13. The method for manufacturing the semiconductor device according to claim 9, wherein the projection has a thermal conductivity higher than that of a portion, other than the projection, of the lower jig.

14. The method for manufacturing the semiconductor device according to claim 9, wherein the lower jig is heated with the lead frame pressed toward the projection.
